(19) United States
(12) Patent Application Publication
(10) Pub. No.: US 2010/0124709 A1
(43) Pub. Date: May 20, 2010

(54) IMAGE MASK ASSEMBLY FOR PHOTOLITHOGRAPHY

(76) Inventors: Daniel Warren Hawtof, Corning, NY (US); Windsor P. Thomas, Painted Post, NY (US)

Correspondence Address: CORNING INCORPORATED, SP-TI-3-1, CORNING, NY, 14831, US

(21) Appl. No.: 12/274,832

(22) Filed: Nov. 20, 2008

(51) Int. Cl. G03F 1/00

(52) U.S. Cl. 430/5

(57) ABSTRACT

An image mask assembly for photolithography. The image mask assembly includes an image mask, a synthetic fused silica pellicle for protecting the image mask, and a frame holding the image mask and pellicle. The image mask includes a synthetic fused silica sheet comprising at least one layer and having a pattern written on a surface of the fused silica sheet. Methods of making the image mask and synthetic fused silica pellicle are also provided.

### BACKGROUND

The invention relates to an image mask assembly for photolithography. More particularly, the invention relates to an image mask and a pellicle for use in an image mask assembly.

Photolithographic patterning is a conventional and established technology in the manufacturing process of precision electronic and display devices, including semiconductor devices, such as integrated circuits, and liquid crystal display (LCD) panels. In the photolithographic patterning process, the surface of the substrate for the device is exposed to actinic radiation, such as ultraviolet light, through a pattern-bearing transparency, or photomask (also referred to herein as an “image mask”).

Image masks currently comprise a monolithic piece of high purity fused silica having a patterned layer of chromium deposited onto a surface of the fused silica piece. Fused silica is expensive and difficult to form. Fused silica plates for image masks are typically cut from boules and require finishing (e.g., cutting, grinding, and polishing) to achieve a polished image mask that is very flat and has a low total thickness variation. For each color filter and thin film transistor application in an LCD panel, up to six image masks are needed. Consequently, materials and finishing each account for about 50% of the cost of the final image mask.

Lower quality glasses, such as borosilicate glasses, have been used as image mask material. However, such glasses are not image mask materials of choice, as they have high thermal expansion, low transmission, and inclusions.

In addition to the image mask, image mask assemblies typically include a frame for holding the image mask and at least one pellicle. The pellicle is typically a polymeric membrane mounted on the frame and is intended to provide dust-proof protection of the image mask. Such membrane pellicles tend to sag due to transient temperature fluctuations during the photolithographic process, are susceptible to tearing and scratching, absorb gaseous hydrocarbons and water, and require application of an anti-reflective coating.

### SUMMARY

The present invention provides an image mask assembly for photolithography. The image mask assembly inc.udes an image mask, a synthetic fused silica pellicle for protecting the image mask, and a frame holding the image mask and pellicle. The image mask includes a synthetic fused silica sheet having a pattern written on a surface of the fused silica sheet. The pellicle is a synthetic fused silica sheet. Methods of making the image mask and synthetic fused silica pellicle are also provided.

Accordingly, one aspect of the invention is to provide an image mask assembly for a photolithographic apparatus. The image mask assembly comprises an image mask and a frame supporting the image mask, wherein the frame is affixed to the image mask around at least a portion of a periphery of the image mask. The image mask comprises a synthetic fused silica sheet having at least one layer and a pattern written on at least a portion of a surface of the synthetic fused silica sheet. The synthetic fused silica sheet has a thickness in a range from about 50 μm up to about 500 μm. The frame and the image mask have coefficients of thermal expansion that differ from each other by less than about 10%. The frame forms an aperture parallel to the surface of the synthetic fused image mask, wherein the pattern is capable of being exposed to radiation through the aperture.

A second aspect of the invention is to provide an image mask for a photolithographic apparatus. The image mask comprises a synthetic fused silica sheet and a pattern written on at least a portion of a surface of the fused silica sheet. The fused silica sheet comprises at least one layer and has a thickness in a range from about 50 μm up to about 500 μm.

A third aspect of the invention is to provide a pellicle for an image mask, wherein the pellicle is a synthetic fused silica sheet comprising at least one layer.

A fourth aspect of the invention is to provide a method of making an image mask. The method comprises the steps of: providing a synthetic fused silica sheet comprising at least one layer and having a thickness in a range from about 50 μm up to about 500 μm; and forming a pattern on at least a portion of a surface of the synthetic fused silica sheet to form the image mask.

A fifth aspect of the invention is to provide a method of making a synthetic fused silica pellicle for an image mask assembly, wherein the pellicle comprises a fused silica sheet. The method comprises the steps of: depositing a plurality of silica soot particles on a deposition surface to form a soot sheet comprising at least one layer, wherein the silica soot particles optionally comprise at least one dopant; releasing at least a portion of the soot sheet from the deposition surface; and sintering at least a portion of the soot sheet to form the synthetic fused silica pellicle.

These and other aspects, advantages, and salient features of the present invention will become apparent from the following detailed description, the accompanying drawings, and the appended claims.

### BRIEF DESCRIPTION OF THE DRAWINGS

FIG. 1 is a schematic cross-sectional view of an image mask assembly;

FIG. 2 is schematic cross-sectional view of a fused silica sheet having an outer region and an inner region;

FIG. 3 is a schematic side view of a continuous deposition process and a portion of an apparatus for forming a fused silica sheet;

FIG. 4 is a schematic side view of a second embodiment of a continuous deposition process and a portion of an apparatus for forming a fused silica sheet; and

FIG. 5a is a schematic top view of a combination of burner arrays that is used to form a soot sheet having outer doped regions and an inner undoped region; and

FIG. 5b is a schematic cross-sectional view the soot sheet formed using the combination of burner arrays shown in FIG. 5a.

### DETAILED DESCRIPTION

In the following description, like reference characters designate like or corresponding parts throughout the several views shown in the figures. It is also understood that, unless otherwise specified, terms such as “top,” “bottom,” “outward,” “inward,” and the like are words of convenience and are not to be construed as limiting terms. In addition, whenever a group is described as comprising at least one of a group of elements and combinations thereof, it is understood that the group may comprise, consist essentially of, or consist of any number of those elements recited, either individually or in combination with each other. Similarly, whenever a group is described as consisting of at least one of a group of elements and/or combinations thereof, it is understood that the group may consist of any number of those elements recited, either individually or in combination with each other. Unless otherwise specified, a range of values, when recited, includes both the upper and lower limits of the range and any smaller range therebetween.

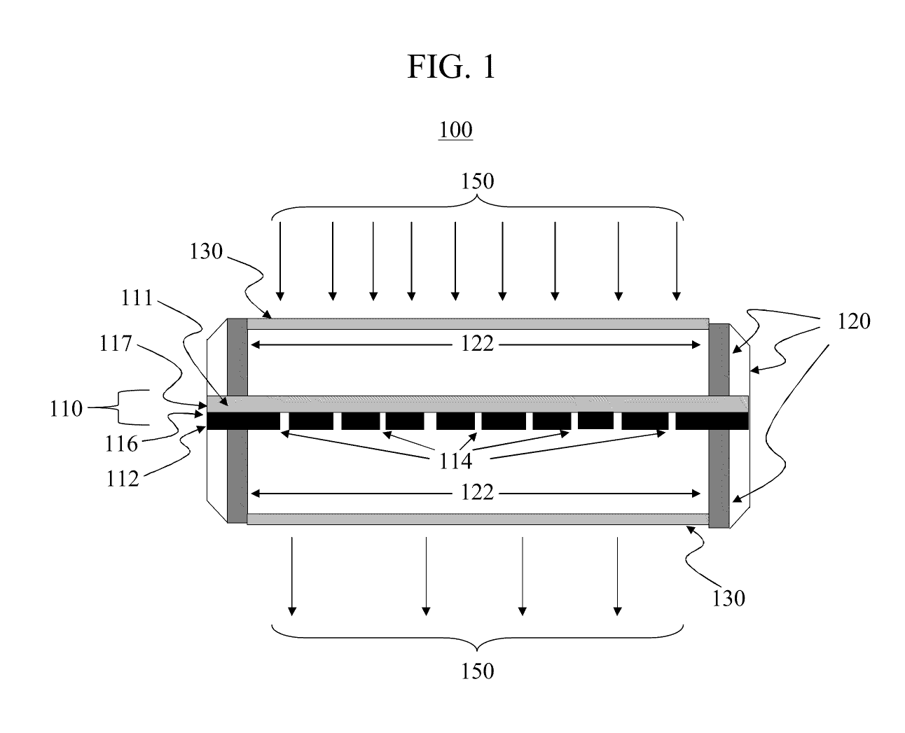

Referring to the drawings in general and to FIG. 1 in particular, it will be understood that the illustrations are for the purpose of describing a particular embodiment of the invention and are not intended to limit the invention thereto. The drawings are not necessarily to scale, and certain features and certain views of the drawings may be shown exaggerated in scale or in schematic in the interest of clarity and conciseness.

Photolithographic patterning is a conventional and established technology in the manufacturing process of precision electronic and display devices, including semiconductor devices, such as integrated circuits, and liquid crystal display (LCD) panels. In the photolithographic patterning process, the surface of the substrate for the device is exposed to actinic radiation, such as ultraviolet light, through a pattern-bearing transparency called a photomask (also referred to herein as an “image mask”).

LCD image masks currently comprise a monolithic piece of high purity fused silica having a patterned layer of chromium deposited onto a surface of the fused silica piece. Image masks are typically used in photolithography equipment to transfer thin film transistor (also referred to herein as “TFT”) or color filter (also referred to herein as “CF”) patterns onto mother glass substrates that are used in LCD display panels. Each chrome coated image mask has a unique pattern written on it. Consequently, the entire image mask must be replaced whenever the design of the chromium pattern is changed or the mask is worn or damaged.

Fused silica is expensive and difficult to form. Fused silica plates for image masks are typically cut from boules (i.e., a bulk body formed by deposition of fine silica particles formed by a synthetic process). The cut fused silica plates require finishing (e.g., cutting, grinding, and polishing) to achieve a polished image mask that is very flat and has a low total thickness variation. Up to six image masks are needed for each CF and TFT application. Consequently, materials and finishing each account for about 50% of the cost of the final image mask.

Among the problems addressed by the present invention is the extensive effort that is needed to finish a photomask for photolithography applications, such as in the writing of binary circuits, semiconductor devices, and TFTs and CFs for LCD applications. The present invention solves these problems by providing an image mask comprising a fused silica sheet having a thickness in a range from about 5 μm up to about 500 μm and a pattern disposed on one surface of the fused silica sheet.

Accordingly, an image mask assembly and an image mask for photolithography applications are provided. A schematic cross-section of an image mask assembly is shown in FIG. 1. Image mask assembly 100 comprises an image mask 110 and a fused silica frame 120 coupled to image mask 110 around the periphery of image mask 110. In the embodiment shown in FIG. 1, image mask assembly 100 further comprises at least one pellicle 130 coupled to frame 120.

Image mask 110 comprises a synthetic fused silica sheet 111 comprising at least one layer and having a thickness in a range from about 50 μm up to about 500 μm and a light-absorbing layer 112 disposed on one surface 116 of synthetic fused silica sheet 111. Fused silica sheet 111 comprises at least one layer and has two surfaces 116 and edges 117 that are located on the periphery of surfaces 116. A transparent pattern 114 is formed in layer 112. Layer 112 is formed by depositing a light-absorbing layer of chromium metal, or any other material known in the art, on surface 116, typically by physical or chemical vapor deposition means known in the art. The chromium layer is subsequently etched using etching methods known in the art to remove portions of the light absorbing layer of chromium metal to produce pattern 114. Radiation 150 from a radiation source (not shown) passes through those portions of transparent pattern 114 in which chromium has been removed to expose a photomask material deposited on a motherglass substrate (not shown), located at a predetermined distance from side of image mask assembly 100 opposite the radiation source. Pattern 114 may be a binary pattern—i.e., a pattern used to make integrated circuits or other features on semi-conducting substrates, or a pattern for making a thin film transistor or color filter on a mother glass in a liquid crystal display. Such patterns that are used to make the desired device features are well known in the photolithography arts. Semi-conductor device features are frequently smaller than the wavelength of the incident radiation 150 (typically less than about 200 nm) used in the photolithographic process, whereas the size of LCD features are limited by visual acuity and are no smaller than about 1 μm.

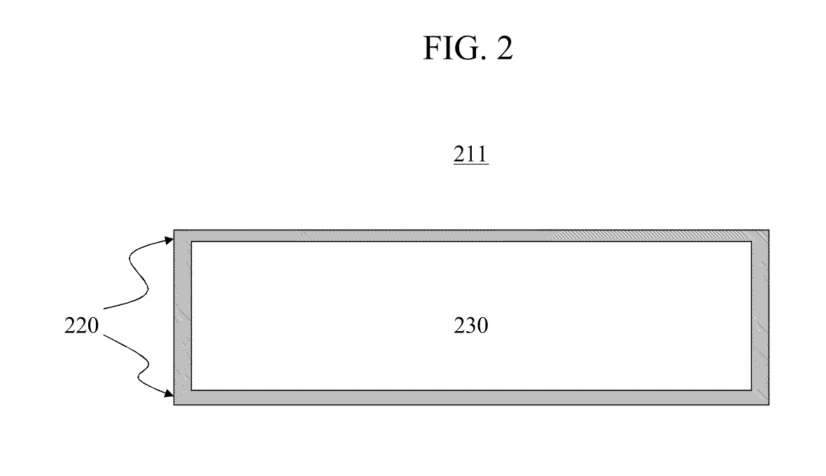

In one embodiment, synthetic fused silica sheet 111 of image mask 110 has an outer region that is under compressive stress, which provides the surfaces of image mask 110 with resistance to abrasion and scratching. A cross-sectional view of a fused silica sheet 211 having an outer region 220 and an inner region 230 is schematically shown in FIG. 2. A central tension is created in inner region 230 of synthetic fused silica sheet 211 to balance the compressive stress in outer region 220. The outer region 220 has a depth of at least about 0.1 μm. In one embodiment, the depth of outer region 220 is in a range from about 0.1 μm up to about 2 μm. The compressive stress in outer region 220 is at least about 10 kpsi (about 69 MPa) and, in one embodiment, ranges from about 10 kpsi up to about 20 kpsi (about 138 MPa).

In one embodiment, the compressive stress in outer region 220 of synthetic fused silica sheet 211 is created by doping the outer region with at least one dopant such as, but not limited to, titania (TiO₂), alumina (Al₂O₃), zirconia (ZrO₂), germania (GeO₂), combinations thereof, and the like. Alternatively, other inorganic oxides may be used to dope the outer region 220 of fused silica sheet 211. The outer region 220 of synthetic fused silica sheet 211 may, in one embodiment, comprise from about 1 wt % up to about 15 wt % and, in a particular embodiment, about 7 wt % of the at least dopant. In a preferred embodiment, outer region 220 comprises about 7 wt % titania.

Fused silica image masks that are currently in use are formed by polishing rough blanks, which are cut from oversized fused silica blocks. The synthetic fused silica sheet 111 of image mask 110 described herein is unpolished, as it is formed as a freestanding sheet by a direct soot deposition process in which at least one soot layer is deposited on a deposition surface and then sintered to form fused silica sheet 111 after removal from the deposition surface. The absence of contact of surfaces 116 of fused silica sheet 111 with other surfaces or materials eliminates the need to polish surfaces 116. By eliminating the polishing step, the cost of making an image mask is reduced by as much as 40%.

Frame 120 supports image mask 110. In one embodiment, frame 120 has an upper portion and a lower portion. In such instances, image mask 110 is positioned flat between the upper and lower portions of frame 120 and fixed in place, for example, using adhesives, gasket materials, or combinations thereof that are known in the art of image mask assembly. Frame 120 forms at least one clear aperture 122 parallel to surface 112, which is exposed to radiation 150 from a light source (not shown) passing through clear aperture 122. In applications involving the processing of semiconductor devices, clear aperture 122 has a maximum dimension of about 6 inches (about 15 cm) square. LCD applications require clear aperture sizes of up to about 2000 cm².

Frame 120 and image mask 110 have coefficients of thermal (CTEs) that closely match or are equal to each other. In one embodiment, the CTEs of frame 120 and image mask 110 differ by less than about 10% from each other, and, in another embodiment, the CTEs of image mask 110 and frame 120 differ by less than about 1%. In yet another embodiment, frame 120 has a coefficient of thermal expansion that is substantially the same as that of image mask 110. By either closely or exactly matching the CTEs of frame 120 and image mask 110, the need for any equalization procedures to compensate for loss of resolution of features written using image mask assembly 100 is eliminated. In one embodiment, frame 120 is formed from fused silica, thus providing a perfect CTE match between image mask 110 and frame 120. Alternatively, frame 120 may be formed from another material—such as, for example, a composite material—that is compatible with the environment encountered in photolithographic stepper systems and has a CTE that either closely matches (i.e., differs by less than about 10%, and, in one embodiment, less than about 1%, from the CTEs of frame 120 and image mask 110) or is substantially the same as that of image mask 110.

Frame 120 is adaptable for securing image mask assembly 100 in various photolithographic stepper devices that are known in the art. As such, Frame 120 may have the same fit and form as those frames known in the art; i.e., frame 120 may have a bevel or chamfer 122 comparable to such frames, thus enabling image mask assembly 100 to be installed and used in existing photolithography systems. In those instances where image mask assembly 100 includes at least one pellicle 130 coupled to frame 120, frame 120 may further include at least one vent (not shown) to equalize pressure inside and outside image mask assembly 100. Such vents may be provided with filters to prevent entry of particulate matter into image mask assembly 100.

In one embodiment, frame 120 comprises fused silica that may be fused together, for example, via laser fusion or other techniques known in the art, to make a permanent structure with image mask 110 and, when present, pellicle 130. In another embodiment, frame 111 comprises fused silica, but is not fused together. In this instance, frame 120 instead includes a gasket or other temporary adhesive known in the art to enable ease of reuse, cleaning, and repair of frame 120.

The quality of photolithographic patterning is adversely affected by dust particles that are present on the photomask due to absorption, scattering, and diffraction of the exposure light. The surface of the image mask must therefore absolutely free from dust particles deposited thereon. Hence, photolithographic patterning processes are conducted in a dust-free atmosphere within a clean room. Even so, it is almost impossible to keep the image mask absolutely free from dust particles, even in a clean room of the highest class. A transparent, framed pellicle is mounted on the frame holding the photomask to provide dust-proof protection of the image mask and the patterning light-exposure is conducted through the transparent pellicle.

Pellicles are typically membranes made of an organic material such as nitrocellulose or other fluorocarbon-based polymers. The use of such pellicle membranes results in a mismatch in coefficients of thermal expansion (CTE) of the pellicle, frame, and image mask. Heat transients in the photolithography process cause fluctuations in temperature and, due to CTE mismatches, flatness of the pellicle. Consequently, the pellicle tends to sag, causing errors in the lithography process. In addition, such pellicle membranes are susceptible to scratching and tearing, particularly during cleaning operations that are intended to remove contaminants. Such organic pellicle membranes also absorb gaseous hydrocarbons and moisture from the atmosphere. These adsorbates tend to decrease transmissivity of the pellicle membrane. Due to their optical properties, polymer pellicle membranes also require application of an anti-reflective membrane to at least one side of the pellicle membrane, thus adding cost and complexity.

The present invention addresses the problems associated with such pellicle membranes by providing a pellicle 130 that is a fused silica sheet having a thickness ranging from about 5 μm up to about 500 μm. The fused silica pellicle is resistant to scratching and tearing and, due to its thinness, does not require application of antireflective coatings. In addition, the problem of CTE mismatch is solved, as the fused silica pellicle described herein has a CTE that either closely matches (i.e., differs by less than about 10%, and, in one embodiment, less than about 1%, from the CTEs of the frame and image mask) or is substantially identical to those of the frame 120 and image mask 110 described herein.

Accordingly, a fused silica pellicle 130 is also provided. Pellicle 130 protects image mask 110 from contamination from particulate matter by providing a physical barrier on the outside of image mask assembly 100. In one embodiment, pellicle 130 is a synthetic fused silica sheet comprising at least one layer and having a thickness in a range from about 5 μm up to about 500 μm. In another embodiment, pellicle 130 has a thickness ranging from about 5 μm up to about 100 μm and, in a third embodiment, pellicle 130 has a thickness ranging from about 50 μm up to about 500 μm. The thinness of pellicle 130 eliminates the need for an anti-reflective coating and allows pellicle to be positioned flat across frame 120 to cover clear aperture 122. Pellicle 130 may be affixed to frame 120, for example, using adhesives, gasket materials, or combinations thereof that are known in the art of image mask/pellicle assembly. A second pellicle (not shown) may be optionally affixed to frame 120 facing the side of mage mask 110 opposite the side of image mask facing pellicle 130. Pellicle 130 is approximately the same size as—or slightly larger than—clear aperture 122 to allow contact with frame 120 and provide complete coverage of aperture 122. Thus, in applications involving the processing of semiconductor devices, pellicle 130 has a maximum dimension of about 6 inches (about 15 cm) square. For LCD applications, pellicle sizes of up to about 2000 cm² are required.

As with synthetic fused silica sheet 111 of image mask 110, pellicle 130 is formed as a freestanding fused silica sheet formed by a soot deposition process. As such, the surfaces of pellicle 130 are formed without any contact with other materials or surfaces during soot fusion or sintering, thus allowing a surface roughness of about 10 Ra/RMS to be achieved. The absence of contact during processing eliminates the need to polish the surfaces of pellicle 13, thus allowing an unpolished fused silica sheet to be used as pellicle 130.

In one embodiment, at least one surface of pellicle 130 has an outer region that is under compressive stress (such as that shown in FIG. 2), which provides the at least one surface of pellicle 130 with resistance to cracking or breakage due to abrasion and scratching. A central tension is created in an inner region of pellicle 130 to balance the compressive stress in the outer region. The outer region has a depth of at least about 0.1 μm. In one embodiment, the depth of the outer region is in a range from about 0.1 μm up to about 2 μm. The compressive stress in the outer region is at least about 10 kpsi (about 69 MPa) and, in one embodiment, ranges from about 10 kpsi up to about 20 kpsi (about 138 MPa).

In one embodiment, the compressive stress in the outer region of pellicle 130 is created by doping the outer region with at least one dopant such as, but not limited to, titania (TiO₂), alumina (Al₂O₃), zirconia (ZrO₂), germania (GeO₂), combinations thereof, and the like. Alternatively, other inorganic oxides may be used to dope the outer region of pellicle 130. In one embodiment, the outer region of pellicle 130 may comprise from about 1 wt % up to about 15 wt % and, in another embodiment, about 7 wt % of the at least one dopant. In a preferred embodiment, the outer region comprises about 7 wt % titania.

Because image mask 100, frame 120, and pellicle 130 are, in one embodiment, formed from fused silica, these three elements of image mask assembly 100 have essentially the same coefficient of thermal expansion (CTE). Image mask assembly 100 is therefore free of CTE mismatch. Differences in CTE results in sagging of the pellicle, which in turn causes decollimation of radiation 150 passing through an image mask assembly. Such decollimation causes distortion of the image projected through an image mask assembly. The image mask assembly 100 described herein eliminates the source of such distortion because the elements of image mask assembly have essentially the same CTE. In addition, sagging of the pellicle is further reduced because pellicle 130 described herein is more rigid than those polymeric membrane pellicles that are currently in use.

In one embodiment, synthetic fused silica sheet 111 of image mask 110 and pellicle 130 are formed by continuous deposition of fused silica soot which, in one embodiment, includes at least one dopant. The continuous deposition of fused silica is described in U.S. patent application Ser. No. 11/800,584, entitled “Process and Apparatus for Making Glass Sheet,” filed on May 7, 2007, by Daniel W. Hawtof et al., the contents of which are incorporated by reference herein in their entirety.

In the continuous deposition process, fused silica particles—which may optionally include at least one dopant described herein—are deposited on a deposition surface to form a soot sheet having a bulk density of about 0.5 g/cm³. subsequent to deposition of the soot sheet, the soot sheet is released from the deposition surface and fused or sintered to forma fully dense fused silica sheet having a density of about 2 g/cm³. In one embodiment, the deposition surface is a curved deposition surface of a rotating drum. The fused silica particles—either doped or undoped—may be formed using those soot deposition methods known in the art such as, but not limited to, sol-gel deposition, outside vapor deposition (OVD), plasma induction vapor deposition, vapor axial deposition (VAD), and the like. Such processes are typically two-step processes comprising a first step of depositing silica soot particles on the outer surface of a mandrel or a drum to form a soot body, followed by a second step of sintering the soot body to form consolidated glass. In each of these processes, soot particles may be formed by passing a silicon-containing precursor such as octamethylcyclotetrasiloxane (OMCTS) or the like, a fuel (such as hydrogen or methane), and an oxidizer through a burner. The silicon-containing precursor is either hydrolyzed or combusted in the burner flame to produce fine silica soot particles.

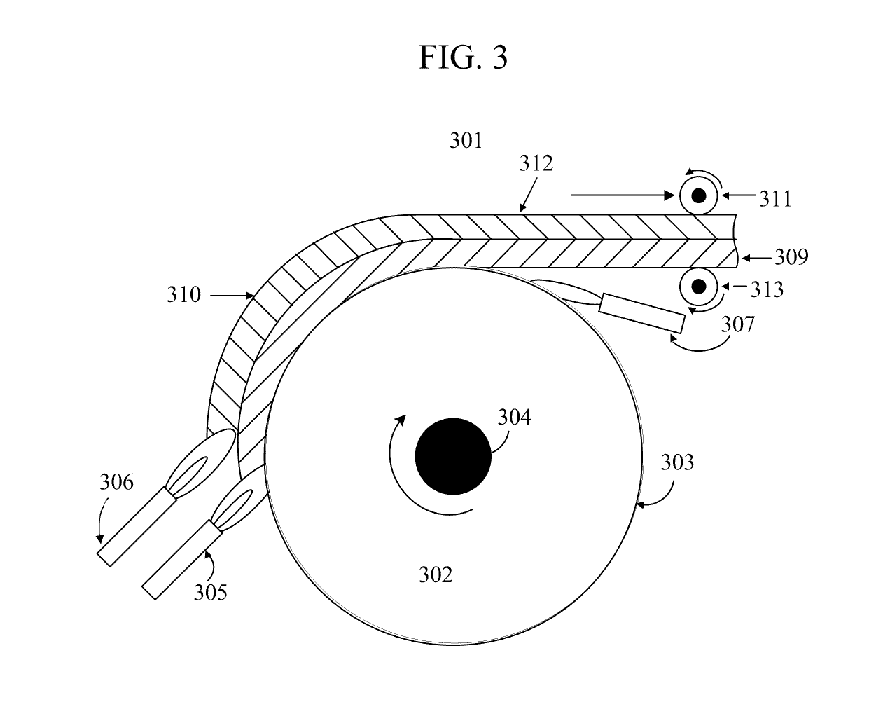

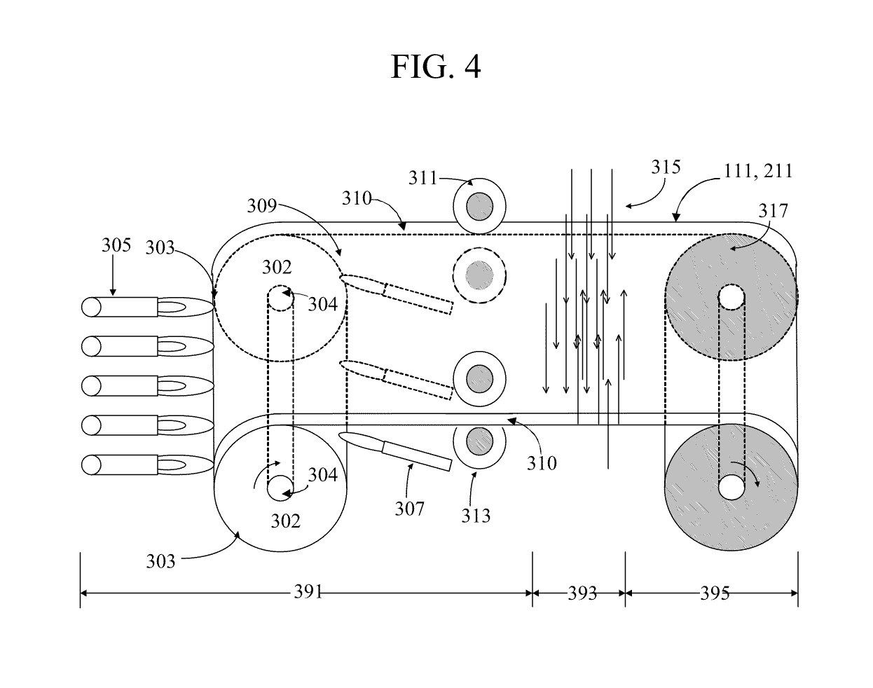

A side view of a continuous deposition process and a portion of an apparatus 301 for forming a doped and/or undoped fused silica sheet for use in the image mask 110 or pellicle 130 described herein are schematically shown in FIG. 3. A side view of a second embodiment of the deposition process and an apparatus 401 for forming a fused silica sheet for use in image mask 110 or as pellicle 130 are schematically shown in FIG. 4.

Apparatus 301, shown in FIG. 3, includes two burners (or two sets of burner arrays) 305, 306 depositing two layers of undoped and/or doped silica soot 309, 310 that together form a soot sheet 312. In some embodiments, burners 305, 306 preferably represent two separate burner arrays, such as those known in the art. In some embodiments, however, a single burner or array of burners may be used to deposit a single layer of soot. Alternatively, more than two burners or arrays of burners 305, 306 may be used to deposit separate soot layers.

The apparatus 401 shown in FIG. 4 has burners 305 (or a single set or array of burners) depositing single layers of silica soot 310 on two separate deposition surfaces 303, which are located on the outer surfaces of drums 302, each rotating around an axis 304. Apparatus 401 may be optionally provided with a second set or array of burners 306 for depositing second layers of soot 309 on deposition surfaces 303. Apparatus 401 has three zones: a soot deposition and releasing zone 391; a sintering zone 393; and a take-up zone 395.

Burner/burner array 305 provides soot particles that are deposited to form base layer 309 of soot. Base layer 309 is in direct contact with the deposition surface 303 of rotating drum 302. Burner/burner array 306 subsequently provides soot particles that are deposited to form additional layer 310 over base layer 309. The thicknesses of base layer 309 and additional layer 310 may be the same or different from each other.

In one embodiment, soot layers 309, 310 have essentially the same chemical composition and physical properties, such as average soot density, average soot particle size, and the like. In other embodiments, soot layers 309, 310 have different compositions, allowing different layers of doped or undoped fused silica to be included within the resulting fused silica sheet 111, 211.

In one embodiment, soot sheet 312 is allowed to remain on deposition surface 303 until completion of the deposition process. After soot sheet 312 having the desired length, width, and thickness is formed, soot sheet 312 can be released from deposition surface 303. While some bonding between base layer 309 and deposition surface 303 is needed during initial formation of soot sheet 312, it is advantageous that such bonding be limited to facilitate release of soot sheet 312. Release of soot sheet 312 from deposition surface 303 may be achieved by at least one of: application of a temperature gradient between the point where soot sheet 312 is deposited and the location where soot sheet 312 is released from deposition surface 303; use of sheet-releasing devices such as, but not limited to, knives, chisels, cutting wires, and threads; gas streams 307; or the like. Soot sheet 312 may be released from deposition surface 303 while drum 310 is either rotating or static.

Once released from deposition surface 303, soot sheet 312 is moved away from deposition surface 303. Continuous movement of soot sheet 312 away from deposition surface 303 after release is advantageously guided by soot-sheet-guiding devices 311, 113, such as rollers or the like, that are in direct contact with a main surface of soot sheet 312 so as to provide support and guidance for soot sheet 312 when it moves. Such soot-sheet-guiding devices 311, 313 may include multiple members that are in direct contact with both main surfaces of soot sheet 312. Soot sheet guiding devices 311, 313 may be either externally powered so as to move soot sheet 312 or passive, and may include guide rollers, conveyor belts, and other means conveyance and/or guidance means known in the art. In one embodiment, the soot-sheet-guiding devices 311, 313 are placed in direct contact substantially only with the peripheral portions (i.e., close to edges) of a main surface of soot sheet 312 to maintain a high surface quality of the soot sheet and avoid contamination and scratching. Referring to FIG. 4, deposition of soot layers 309, 310 takes place in deposition and release zone 391.

To form fused silica sheet 111, 211, soot sheet 312 is subjected to a sintering step in which soot sheet 312 is sintered or consolidated (as used herein, the terms “sintering” and “consolidation” refer to the same process and are used interchangeably) into a dense sheet of fused silica. Referring to FIG. 4, the sintering step takes place in sintering zone 393. In one embodiment, a continuously moving soot sheet 312 is fed into sintering zone 393, where at least a portion of soot sheet 312 is heated to a high temperature for a period of time that is sufficient to consolidate soot sheet 312 into fused silica sheet 111, 211. The times and temperatures needed to consolidate soot sheet 312 into fused silica are known by those skilled in the art. Temperatures in the range from about 1500° C. up to about 2000° C., for example, are typically used to sinter and consolidate soot into fused silica. Various heating sources known in the art, such as electrical resistance heating, induction heating, combinations thereof, and the like may be used to sinter and consolidate soot sheet 312 at a substantially uniform temperature. It is desirable to heat both sides of soot sheet of soot sheet 312. In some embodiments, it is desirable to carry out sintering/consolidation of soot sheet 312 in an inert gas (e.g., nitrogen, helium, argon, combinations thereof, and the like) to improve heat transfer and prevent oxidation. The sintered fused silica sheet may be optionally annealed at temperatures that are less than or equal to the strain point of the fused silica to remove stress.

During sintering/consolidation, soot sheet 312 may be held stationary in a sintering zone 393 (FIG. 4). Large soot sheets may be sintered incrementally. In those embodiments where the deposition of soot sheet 312 is continuous, soot sheet 312 is passed through sintering zone 393 continuously such that soot sheet can be sintered sequentially, thus allowing for continuous production of fused silica sheet 111, 211.

Outer edge regions of fused silica sheets, may, in some embodiments, not be sintered. The unsintered edge regions may be trimmed away using a laser or other cutting devices known in the art.

Once sintered and consolidated, a continuous fused silica sheet 111, 211 can be reeled into a roll by a take-up device 317 in take-up zone 395 (FIG. 4). Spacing materials such as paper, cloth coating materials, and the like may be inserted between adjacent glass surfaces to prevent direct contact therebetween. The fused silica sheet may then later be cut to the size of image mask 110 or pellicle 130 and affixed to frame 120.

As described herein, at least one of fused silica sheet 211 of image mask 110 and pellicle 130 has an outer region 220 that comprises at least one dopant such as, for example, titania, alumina, zirconia, germania, or the like. The dopant is co-deposited with silica in the deposition of the soot sheet. As previously mentioned, multiple burners or burner arrays may be used to deposit different layers 309, 310 of soot, forming a soot sheet 312 (FIGS. 3 and 4) that is ultimately sintered to form fused silica sheet 111, 211 or pellicle 130, and the compositions of such layers may differ from each other. Thus, to achieve the desired doping of the outer region of the fused silica sheet 111, 211 or pellicle 130, multiple burner arrays may be used to sequentially deposit layers of doped and undoped silica soot.

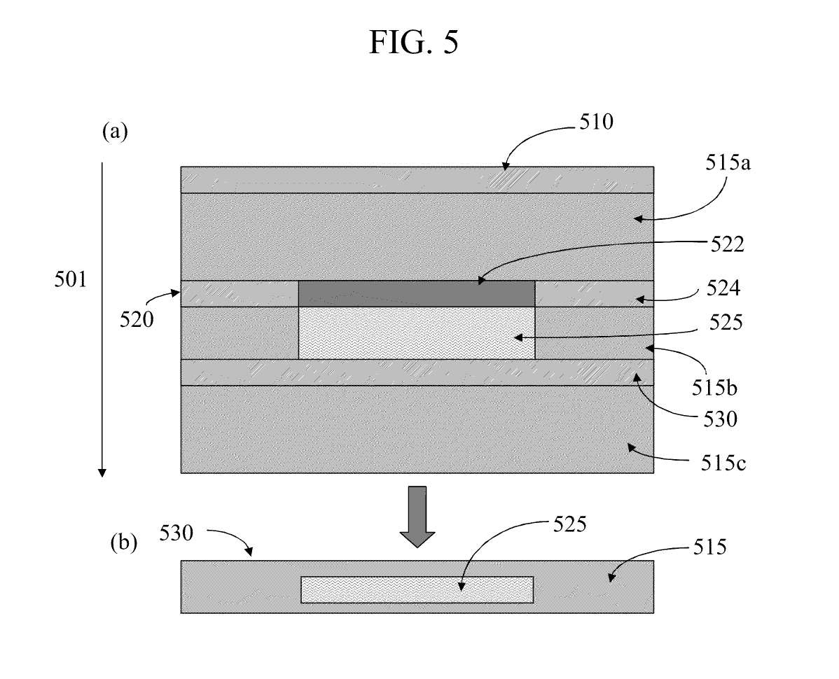

A top view of a combination of burner arrays that may be used to form a soot sheet having outer doped regions and an inner undoped region is schematically shown in FIG. 5a. While formation of a soot sheet having titania-doped layers is described below, it is understood that the soot sheet may be doped with other materials using the principles described herein.

Referring to FIG. 5a, the various doped and undoped layers of silica soot are deposited as the silica soot sheet travels in direction 501. A first burner array 510 deposits a first layer of titania-doped silica soot 515a. In addition to at least one silicon-containing precursor, a fuel, and an oxidizer, a titanium-containing precursor such as titanium chloride (TiCl₄), titanium isopropoxide, other titanium halides or organometallic titanium compounds known in the art, or the like is provided to first burner array 510, where the silicon- and titanium-containing precursors are either hydrolyzed or combusted in the flame to produce a first layer of fine titania-doped silica soot particles. In those instances where the dopant is a material other than titania, volatile precursors of the dopant, such as metal halides or organometallic compounds that may or may not be analogous to those described for doping with titania, may be used. The first deposited layer of titania-doped silica soot 515a then passes through a flame generated by a second burner array 520. Second burner array 520 comprises an inner portion 522 and outer portions 524 abutting inner portion 522. A silicon-containing precursor, fuel, and oxidizer are provided to inner portion 522 of second burner array 520. The silicon-containing precursor is either hydrolyzed or combusted in the flame produced by first portion 522, depositing a layer of fine undoped silica soot particles 525 over a center portion of the first deposited layer. Outer portions 524 are provided with silicon- and titanium-containing precursors, fuel, and oxidizer. The silicon- and titanium-containing precursors are either hydrolyzed or combusted in the flame produced by outer portion 524 to deposit a second layer of fine titania-doped silica soot particles 515b over the outer portions of the first layer. The soot sheet with first and second deposited layers then passes through a flame generated by a third burner array 530. A titanium-containing precursor, a silicon-containing precursor, fuel, and oxidizer, are provided to third array 530, where the silicon- and titanium-containing precursors are either hydrolyzed or combusted in the flame to deposit a third layer of fine titania-doped silica soot particles 515c over the second layer. A cross-sectional view of the resulting soot sheet 530 is schematically shown in FIG. 5b. Soot sheet 530 is then sintered/consolidated to form a fused silica glass sheet, such as that shown in FIG. 2. The resulting fused silica sheet has a doped outer region 515 under compressive stress and an undoped inner region 525.

The process of continuous inline soot deposition and sintering allows for a pristine surface quality which does not require any surface treatment, such as grinding, lapping, or polishing prior to use as a pellicle or image mask, thus greatly decreasing cost and also improving optical quality. The continuous doped silica deposition technique described herein is capable of being scaled in size to make pellicles and image mask materials as large as required. For LCD lithography, pellicles and fused silica sheets for image masks may have dimensions of up to about 2030 mm×2030 mm.

The inline sintering of the pellicle and image mask using the methods described herein is performed in a controlled environment and without any contact through the processing steps. The methods described herein also provide a fused silica sheet having a surface roughness on the order of 10 A Ra/RMS. The thickness variation can also be controlled through precision deposition and subsequent sintering.

While typical embodiments have been set forth for the purpose of illustration, the foregoing description should not be deemed to be a limitation on the scope of the invention. For example, dopants other than titania may be used to provide compressive stress to the outer region of the pellicle and fused silica sheet portion of the image mask. In addition to dopant addition, stress in the fused silica sheet may also be removed with inline annealing as needed. Accordingly, various modifications, adaptations, and alternatives may occur to one skilled in the art without departing from the spirit and scope of the present invention.

1. An image mask assembly for a photolithographic apparatus, the image mask assembly comprising:
a. an image mask, wherein the image mask comprises a synthetic fused silica sheet having at least one layer and a pattern written on at least of portion of a surface of the synthetic fused silica sheet, wherein the synthetic fused silica sheet has a thickness in a range from about 50 μm up to about 500 μm; and
b. a frame supporting the image mask, wherein the frame is affixed to the image mask around at least a portion of a periphery of the image mask, wherein the frame and the image mask have coefficients of thermal expansion that differ from each other by less than about 10%, wherein the frame forms an aperture parallel to the surface of the synthetic fused silica sheet, and wherein the pattern is capable of being exposed to radiation through the aperture.

2. The image mask assembly of claim 1, further comprising a synthetic fused silica pellicle for protecting the image mask from contamination, the fused silica pellicle being affixed around its periphery to the frame and held parallel to the image mask by the frame, and wherein the pellicle has a coefficient of thermal expansion that differs from the coefficients of thermal expansion of the image mask and the frame by less than about 10%.

3. The image mask of claim 2, wherein the fused silica pellicle is a synthetic fused silica sheet having a thickness in a range from about 5 μm up to about 100 μm.

4. The image mask assembly of claim 1, wherein the surface of the image mask is unpolished.

5. The image mask assembly of claim 1, wherein the image mask has an outer region extending inward from the surface, and wherein the outer region further comprises at least one dopant.

6. The image mask assembly of claim 5, wherein the at least one dopant comprises at least one of titania, alumina, zirconia, germania, and combinations thereof.

7. The image mask assembly of claim 5, wherein the outer region is under a compressive stress.

8. The image mask assembly of claim 7, wherein the compressive stress is at least 10 kpsi.

9. The image mask assembly of claim 1, wherein the frame comprises fused silica.

10. The image mask assembly of claim 1, wherein the pattern is one of a thin film transistor pattern, a color filter pattern, and a binary pattern.

11. The image mask assembly of claim 1, wherein the frame is adaptable for securing the image mask assembly within a photolithographic stepper apparatus.

12. An image mask for a photolithographic apparatus, wherein the image mask comprises a synthetic fused silica sheet and a pattern written on portion of a surface of the synthetic fused silica sheet, wherein the fused silica sheet comprises at least one layer and has a thickness in a range from about 50 μm up to about 500 μm.

13. The image mask of claim 12, wherein the surface of the image mask is unpolished.

14. The image mask of claim 12, wherein the image mask has an outer region extending inward from the surface, and wherein the outer region comprises at least one dopant.

15. The image mask of claim 14, wherein the at least one dopant comprises at least one of titania, alumina, zirconia, germania, and combinations thereof.

16. The image mask of claim 14, wherein the outer region is under a compressive stress.

17. The image mask of claim 16, wherein the compressive stress is at least 10 kpsi.

18. A pellicle for an image mask, wherein the pellicle is a synthetic fused silica sheet comprising at least one layer and having a thickness in a range from about 5 μm up to about 100 μm.

19. The pellicle of claim 18, wherein the pellicle has a surface roughness of about 10 Ra.

20. The pellicle assembly of claim 18, wherein the image mask has an outer region extending inward from the surface, and wherein the outer region comprises at least one dopant.

21. The pellicle of claim 20, wherein the at least one dopant comprises at least one of titania, alumina, zirconia, germania, and combinations thereof

22. The pellicle of claim 20, wherein the outer region is under a compressive stress.

23. The pellicle of claim 22, wherein the compressive stress is at least 10 kpsi.

24. A method of making an image mask, the method comprising the steps of:
a. providing a synthetic fused silica sheet, the synthetic fused silica sheet comprising at least one layer and having a thickness in a range from about 50 μm up to about 500 μm, wherein the silica sheet is formed by
i. depositing a plurality of silica soot particles on a deposition surface to form at least one soot layer, wherein the silica soot particles optionally comprise at least one dopant;
ii. releasing at least a portion of the at least one soot layer from the deposition surface; and
iii. sintering at least a portion of the at least one soot layer to form the synthetic fused silica sheet; and
b. forming a pattern on at least of portion of a surface of the synthetic fused silica sheet to form the image mask.

25. A method of making a synthetic fused silica pellicle for an image mask assembly, the pellicle comprising a synthetic fused silica sheet, the method comprising the steps of:
a. depositing a plurality of silica soot particles on a deposition surface to form at least one soot layer, wherein the silica soot particles comprise at least one dopant;
b. releasing at least a portion of the at least one soot layer from the deposition surface; and
c. sintering at least a portion of the at least one soot layer to form the synthetic fused silica pellicle.
